(19) United States
(12) Patent Application Publication
(10) Pub. No.: US 2024/0368753 A1
(43) Pub. Date: Nov. 7, 2024

(54) CHEMICAL LIQUID, MANUFACTURING METHOD OF MODIFIED SUBSTRATE, AND MANUFACTURING METHOD OF LAMINATE

(71) Applicant: FUJIFILM Corporation, Tokyo (JP)

(72) Inventors: Akihiro Hakamata, Haibara-gun (JP); Atsushi Mizutani, Haibara-gun (JP)

(73) Assignee: FUJIFILM Corporation, Tokyo (JP)

(21) Appl. No.: 18/774,832

(22) Filed: Jul. 16, 2024

Related U.S. Application Data
(63) Continuation of application No. PCT/JP2022/047376, filed on Dec. 22, 2022.

(30) Foreign Application Priority Data
Jan. 17, 2022 (JP) 2022-005351

(51) Int. Cl. C23C 16/04; C23C 16/02; C23C 16/40; C23C 16/455; H01L 21/027

(52) U.S. Cl. CPC C23C 16/042; C23C 16/0227; C23C 16/40; C23C 16/45525; H01L 21/027

(57) ABSTRACT

An object of the present invention is to provide a chemical liquid for manufacturing a semiconductor, which is capable of forming a film exhibiting a high contact angle of water on a metal region in a case where the chemical liquid is brought into contact with a substrate having a metal region. The chemical liquid of a semiconductor manufacturing method of the present invention is a chemical liquid for manufacturing a semiconductor including a solvent and two or more specific compounds, in which the specific compound is a compound having a polar group and a vertical alignment group.

### CROSS-REFERENCE TO RELATED APPLICATIONS

This application is a Continuation of PCT International Application No. PCT/JP2022/047376 filed on Dec. 22, 2022, which claims priority under 35 U.S.C. § 119 (a) to Japanese Patent Application No. 2022-005351 filed on Jan. 17, 2022. The above applications are hereby expressly incorporated by reference, in their entirety, into the present application.

### BACKGROUND OF THE INVENTION

### 1. Field of the Invention

The present invention relates to a chemical liquid, a manufacturing method of a modified substrate, and a manufacturing method of a laminate.

### 2. Description of the Related Art

With the further miniaturization of semiconductor devices, there is a demand for the formation of finer and more precise semiconductor elements. In the related art, photolithography has been used in the formation of a semiconductor element, but it requires registration of patterns or the like, and is no longer able to meet the accuracy required these days.

Accordingly, as a method for forming a semiconductor element, a method has been studied in which, utilizing selective adsorption of a compound to a region formed of a specific material, a film consisting of such a compound is selectively formed, and the film is used to treat a region other than the region formed of a specific material. For example, JP2016-040382A discloses a composition containing a corrosion inhibitor, and states that the corrosion inhibitor forms an insoluble coating film on the surface of copper, making it possible to remove other members while preventing corrosion of the copper.

### SUMMARY OF THE INVENTION

As described above, a film formed on a region formed of a specific material (for example, a metal region) is required to exhibit a high contact angle of water, depending on the treatment to be carried out. As a result of studying a film formed of the composition disclosed in JP2016-040382A, the present inventors have found that the contact angle of water in the formed film is not necessarily high and further improvement is necessary.

Therefore, an object of the present invention is to provide a chemical liquid for manufacturing a semiconductor, which is capable of forming a film exhibiting a high contact angle of water on a metal region in a case where the chemical liquid is brought into contact with a substrate having a metal region.

Another object of the present invention is to provide a manufacturing method of a modified substrate using the above-mentioned chemical liquid and a manufacturing method of a laminate.

As a result of extensive studies to achieve the foregoing objects, the present inventors have completed the present invention. That is, the present inventors have found that the foregoing objects can be achieved by the following configurations.

[1] A chemical liquid for manufacturing a semiconductor, comprising a solvent and two or more specific compounds, in which the specific compound is a compound having a polar group and a vertical alignment group.

[2] The chemical liquid according to [1], in which the polar group is one or more groups selected from the group consisting of a nitrogen-containing group, a phosphate group or a salt thereof, a phosphonate group or a salt thereof, a sulfo group or a salt thereof, a carboxy group or a salt thereof, a thiol group, and a hydroxy group.

[3] The chemical liquid according to [1] or [2], in which the chemical liquid contains a first specific compound having a nitrogen-containing group that is the polar group and the vertical alignment group, and a second specific compound having the polar group other than the nitrogen-containing group and the vertical alignment group.

[4] The chemical liquid according to [3], in which the polar group of the second specific compound is a phosphonate group or a salt thereof, a carboxy group or a salt thereof, or a thiol group.

[5] The chemical liquid according to [1] or [2], in which the chemical liquid contains two or more third specific compounds having the polar group selected from the group consisting of a nitrogen-containing group, a phosphonate group or a salt thereof, a carboxy group or a salt thereof, and a thiol group and the vertical alignment group, and the polar groups in the two or more third specific compounds are the same.

[6] A chemical liquid for manufacturing a semiconductor, comprising a solvent and two or more specific compounds, in which the specific compound has a polar group, and a specific group selected from the group consisting of a hydrocarbon group which may have a halogen atom and a polyoxyalkylene group.

[7] The chemical liquid according to [6], in which the polar group is one or more groups selected from the group consisting of a nitrogen-containing group, a phosphate group or a salt thereof, a phosphonate group or a salt thereof, a sulfo group or a salt thereof, a carboxy group or a salt thereof, a thiol group, and a hydroxy group.

[8] The chemical liquid according to [6] or [7], in which the chemical liquid contains a fourth specific compound having a nitrogen-containing group that is the polar group and the specific group, and a fifth specific compound having the polar group other than the nitrogen-containing group and the specific group.

[9] The chemical liquid according to [8], in which the polar group of the fifth specific compound is a phosphonate group or a salt thereof, a carboxy group or a salt thereof, or a thiol group.

[10] The chemical liquid according to [6] or [7], in which the chemical liquid contains two or more sixth specific compounds having the polar group selected from the group consisting of a nitrogen-containing group, a phosphonate group or a salt thereof, a carboxy group or a salt thereof, and a thiol group and the specific group, and the polar groups in the two or more sixth specific compounds are the same.

[11] The chemical liquid according to any one of [1] to [10], in which the one or more specific compounds have a molecular weight of 600 or less.

[12] The chemical liquid according to any one of [1] to [11], in which the chemical liquid is used for treating a substrate having a metal region.

[13] The chemical liquid according to [12], in which the metal region contains tungsten or ruthenium.

[14] The chemical liquid according to any one of [1] to [13], in which the chemical liquid is used for forming a film containing the two or more specific compounds only on a metal region.

[15] The chemical liquid according to any one of [1] to [14], in which the chemical liquid is used for forming a film containing the two or more specific compounds that functions as a mask in a case where a film is formed on a substrate by chemical vapor deposition.

[16] A manufacturing method of a modified substrate, comprising a step of bringing the chemical liquid according to any one of [1] to into contact with a substrate having a metal region to form a film containing the two or more specific compounds on the metal region to obtain a modified substrate.

[17] The manufacturing method of a modified substrate according to [16], in which the step is a step of bringing the chemical liquid into contact with the substrate, heating the substrate with which the chemical liquid has been brought into contact, and subjecting the heated substrate to a rinsing treatment to obtain a modified substrate including a film containing the two or more specific compounds formed on the metal region.

[18] A manufacturing method of a laminate, further comprising a step of subjecting a modified substrate manufactured by the method according to or to atomic layer deposition to form a metal film or a metal oxide film on a region other than the metal region.

[19] The manufacturing method of a laminate according to [18], further comprising a step of removing a film containing the two or more specific compounds formed on the metal region.

[20] According to the present invention, it is possible to provide a chemical liquid for manufacturing a semiconductor, which is capable of forming a film exhibiting a high contact angle of water on a metal region in a case where the chemical liquid is brought into contact with a substrate having a metal region.

In addition, according to the present invention, it is also possible to provide a manufacturing method of a modified substrate using the above-mentioned chemical liquid, and a manufacturing method of a laminate.

### DESCRIPTION OF THE PREFERRED EMBODIMENTS

Hereinafter, the present invention will be described in more detail.

The description of the configuration requirements described below may be made based on the representative embodiments of the present invention, but the present invention is not limited to such embodiments.

Hereinafter, the meaning of each description in the present specification will be shown.

Any numerical range expressed using “to” in the present specification refers to a range including the numerical values before and after the “to” as a lower limit value and an upper limit value, respectively.

In the present specification, with regard to the bonding direction of a divalent group (for example, —COO—), unless otherwise specified, in a case where Y in a compound represented by “X—Y—Z” is —COO—, the compound may be either “X—O—CO-Σ” or “X—CO—O—Z”.

A chemical liquid for manufacturing a semiconductor according to an embodiment of the present invention (hereinafter, also simply referred to as a “chemical liquid”) contains a solvent and two or more specific compounds.

The first embodiment of the chemical liquid contains, as the specific compound, a compound containing a polar group and a vertical alignment group (hereinafter, also referred to as a “compound 1”). The second embodiment of the chemical liquid contains, as the specific compound, a compound having a polar group and a specific group selected from the group consisting of a hydrocarbon group which may have a halogen atom and a polyoxyalkylene group (hereinafter, also referred to as a “compound 2”).

Although the mechanism by which a film exhibiting a high contact angle of water can be formed on a metal region by the chemical liquid according to the embodiment of the present invention (first embodiment and second embodiment) in a case where the chemical liquid is brought into contact with a substrate having a metal region is not necessarily clear, the present inventors speculate as follows.

Since the chemical liquid according to the embodiment of the present invention contains a specific compound and the specific compound has a polar group, the polar group of the specific compound is likely to be adsorbed onto the surface of a metal region, in a case where the chemical liquid is brought into contact with a substrate having a metal region. In addition, since the specific compound has a vertical alignment group or a specific group, the specific compound is arranged substantially vertically to the surface of the metal region, and a dense film containing the specific compound is likely to be formed. Furthermore, it is considered that, in a case where the chemical liquid according to the embodiment of the present invention contains two or more specific compounds, a denser film containing the specific compounds is likely to be formed. In the formed film containing the specific compound, the polar group of the specific compound tends to be arranged facing the surface side of the metal region and a dense film is formed, and as a result, a film exhibiting a high contact angle of water can be formed on the metal region.

Hereinafter, components that can be contained in each embodiment of the chemical liquid according to the embodiment of the present invention will be described.

Hereinafter, a film that is formed on a metal region and exhibits a high contact angle of water in a case where the chemical liquid is brought into contact with a substrate having a metal region is also referred to as a “high contact angle film”, and the fact that the contact angle of water in the high contact angle film is larger is also simply referred to as “the contact angle is larger.”

### First Embodiment of Chemical Liquid

The first embodiment of the chemical liquid according to the embodiment of the present invention contains a solvent and two or more specific compounds.

In addition, as described above, the specific compound is the compound 1.

### [Solvent]

The first embodiment of the chemical liquid according to the embodiment of the present invention contains a solvent. In this regard, even in a case where it is a solvent, it is not included in the solvent in a case where it falls under the specific compound which will be described in detail later.

Examples of the solvent include water and an organic solvent.

Examples of the organic solvent include a hydrocarbon-based solvent, an alcohol-based solvent, a polyol-based solvent, a glycol ether-based solvent, an ether-based solvent, a ketone-based solvent, an amide-based solvent, a sulfur-containing solvent, and an ester-based solvent.

Examples of the hydrocarbon-based solvent include an aliphatic hydrocarbon-based solvent such as n-pentane or n-hexane; an alicyclic hydrocarbon-based solvent such as cyclohexane or methylcyclohexane; and an aromatic hydrocarbon-based solvent such as toluene or xylene.

Examples of the alcohol-based solvent include an aliphatic alcohol-based solvent having 1 to 18 carbon atoms such as methanol, ethanol, 1-propanol, 2-propanol (also referred to as isopropyl alcohol (IPA)), 2-butanol, isobutyl alcohol, tert-butyl alcohol, isopentyl alcohol, or 4-methyl-2-pentanol (also referred to as methyl isobutyl carbinol (MIBC)); an alicyclic alcohol-based solvent having 3 to 18 carbon atoms such as cyclohexanol; an aromatic alcohol-based solvent such as benzyl alcohol; and a ketone alcohol-based solvent such as diacetone alcohol.

The number of carbon atoms in the alcohol-based solvent is preferably 1 to 8, more preferably 2 to 7 and still more preferably 3 to 6.

Examples of the polyol-based solvent include a glycol-based solvent having 2 to 18 carbon atoms.

Examples of the glycol-based solvent include ethylene glycol, propylene glycol (1,2-propanediol), 1,3-propanediol, diethylene glycol, and dipropylene glycol.

Examples of the glycol ether-based solvent include a glycol monoether-based solvent having 3 to 19 carbon atoms.

Examples of the glycol monoether-based solvent include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol monomethyl ether, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

The number of carbon atoms in the glycol ether-based solvent is preferably 1 to 8, more preferably 2 to 7, and still more preferably 3 to 6.

Examples of the ketone-based solvent include acetone, methyl ethyl ketone, methyl isobutyl ketone, and cyclohexanone.

Examples of the ether-based solvent include diethyl ether, diisopropyl ether, dibutyl ether, t-butyl methyl ether, cyclohexyl methyl ether, and tetrahydrofuran.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the sulfur-containing solvent include dimethyl sulfone, dimethyl sulfoxide, and sulfolane.

Examples of the ester-based solvent include n-butyl acetate, ethyl lactate, propylene glycol acetate, propylene glycol monomethyl ether acetate, γ-butyrolactone, and 8-valerolactone.

Above all, the solvent is preferably an organic solvent and more preferably an alcohol-based solvent.

In the first embodiment of the chemical liquid, the content of the solvent in the chemical liquid is preferably 90% to 99.9% by mass, more preferably 95% to 99.9% by mass, and still more preferably 97% to 99.5% by mass with respect to the total mass of the chemical liquid.

Two or more solvents may be used in combination.

In a case where two or more solvents are used in combination, the total content thereof is preferably within the above-mentioned range.

### [Specific Compound]

The first embodiment of the chemical liquid according to the embodiment of the present invention contains two or more specific compounds. Examples of the specific compound include the compound 1.

The expression that the chemical liquid contains two or more specific compounds means that the chemical liquid contains two or more specific compounds different in structure. Different in structure means that the structures of two specific compounds are not the same and include, for example, that the types of polar groups in the two specific compounds are different from each other, and that the types of vertical alignment groups in the two specific compounds are different from each other.

Hereinafter, the polar group and the vertical alignment group will be described.

### (Polar Group)

The polar group contained in the specific compound refers to a group that is polarized, and is preferably a group that interacts with atoms on the surface of the metal region.

From the viewpoint of being capable of interacting with atoms on the surface of the metal region, the polar group is preferably one or more groups selected from the group consisting of a nitrogen-containing group, a phosphate group (—PO₄H₂) or a salt thereof, a phosphonate group (—PO₃H₂) or a salt thereof, a sulfo group (—SO₃H) or a salt thereof, a carboxy group (—COOH) or a salt thereof, a thiol group (—SH), and a hydroxy group (—OH).

Examples of the nitrogen-containing group include a primary amino group (—NH₂), a secondary amino group (—NR^{T}H), a tertiary amino group (—NR^{T}₂), and a quaternary ammonium group (—N⁺R^{T}₃). R^{T} represents an alkyl group having 1 to 3 carbon atoms, and a plurality of R^{T}'s may be different from each other. In addition, a plurality of R^{T}'s may be bonded to each other to form a ring. The ring to be formed is a ring containing a nitrogen atom, examples of which include a pyrrolidine ring, a piperidine ring, and a piperazine ring.

In addition, the nitrogen-containing group may be a nitrogen-containing heteroaryl group which may be monocyclic or polycyclic. Examples of the nitrogen-containing heteroaryl group include a pyridyl group, a triazine group, a pyrrole group, a pyrazole group, an imidazole group, a triazole group, a benzimidazole group, and a benzotriazole group.

The salt of the phosphate group refers to a group represented by —PO₄²⁻Ctⁿ⁺_{2/n}. Ctⁿ⁺ represents an n-valent cation, where n represents 1 or 2. Examples of the monovalent cation include Li⁺, Na⁺, K⁺, and NH₄⁺. In a case where Ctⁿ⁺ represents a monovalent cation, the number thereof is 2. Examples of the divalent cation include Mg⁺ and Ca⁺. In a case where Ctⁿ⁺ represents a divalent cation, the number thereof is 1.

The compound having a phosphate group is also referred to as a “phosphate compound”, and the functional group name is also referred to as “-phosphate”.

The salt of the phosphonate group refers to a group represented by —PO₃²⁻Ctⁿ⁺_{2/n}. Ctⁿ⁺ represents an n-valent cation, where n represents 1 or 2. Examples of the monovalent cation and the divalent cation include the same cations as the cations described in the salt of the phosphate group above, and the numbers thereof are also the same.

The compound having a phosphonate group is also referred to as a “phosphonate compound”.

The salt of the sulfo group refers to a group represented by —SO₃⁻Ct⁺. Ct⁺ represents a monovalent cation, examples of which include the same cations as the monovalent cations described in the salt of the phosphate group above.

The salt of the carboxy group refers to a group represented by —COO⁻Ct⁺. Ct⁺ represents a monovalent cation, examples of which include the same cations as the monovalent cations described in the salt of the phosphate group above.

Above all, from the viewpoint that the contact angle is larger, the polar group is preferably one or more groups selected from the group consisting of a primary amino group, a secondary amino group, a tertiary amino group, a quaternary ammonium group, a phosphate group, a phosphonate group, a sulfo group, a carboxy group, a thiol group, and a hydroxy group; more preferably one or more groups selected from the group consisting of a primary amino group, a phosphonate group, a carboxy group, a thiol group, and a hydroxy group; and still more preferably one or more groups selected from the group consisting of a primary amino group, a phosphonate group, a carboxy group, and a thiol group.

The number of polar groups that the specific compound has is preferably 1 to 4, more preferably 1 or 2, and still more preferably 1.

As will be described later, in a case where the vertical alignment group has a linear structure, the polar group that the specific compound has is preferably bonded to the terminal of the linear structure.

### (Vertical Alignment Group)

The vertical alignment group that the specific compound has refers to a group that has the function of aligning the specific compound itself in a direction vertical to the surface of a metal region, in a case where a chemical liquid containing the specific compound is brought into contact with a substrate having a metal region to form a film containing the specific compound on the metal region.

The vertical alignment group is not particularly limited, and is preferably a group selected from the group consisting of a hydrocarbon group which may have a halogen atom and a polyoxyalkylene group (hereinafter, also referred to as a “specific group”).

The hydrocarbon group is preferably an aliphatic hydrocarbon group and more preferably an alkyl group.

The number of carbon atoms in the hydrocarbon group is not particularly limited, and is preferably 3 to 20, more preferably 6 to 20, and still more preferably 10 to 18.

The hydrocarbon group may have a halogen atom. In a case where the hydrocarbon group has a halogen atom, the number of halogen atoms is not particularly limited and is preferably 1 to 10 and more preferably 1 to 5.

Examples of the halogen atom include a fluorine atom, a chlorine atom, a bromine atom, and an iodine atom.

The hydrocarbon group is preferably linear. For example, an n-butyl group and a 3-chloro-n-butyl group are linear, and an isobutyl group is not linear.

The polyoxyalkylene group is a group having a plurality of oxyalkylene groups, and examples thereof include a polyoxyethylene group and a polyoxypropylene group.

The number of repeating units of an oxyalkylene group in the polyoxyalkylene group is not particularly limited, and is preferably 2 to 20 and more preferably 3 to 10.

The specific compound contained in the first embodiment of the chemical liquid is preferably a compound represented by Formula (A).

X^{a}—Y^{a} Formula (A)

In Formula (A), X^{a} represents a polar group, and Y^{a} represents a hydrocarbon group which may have a halogen atom or a polyoxyalkylene group-containing group. The hydrocarbon group which may have a halogen atom and the polyoxyalkylene group-containing group, represented by Y^{a}, are vertical alignment groups.

The polar group represented by X^{a} is as described above.

The hydrocarbon group which may have a halogen atom, represented by Y^{a}, is as described above. The hydrocarbon group represented by Y^{a} is preferably an alkyl group which may have a halogen atom, and more preferably a linear alkyl group which may have a halogen atom.

The polyoxyalkylene group-containing group represented by Y^{a} is a group containing the above-mentioned polyoxyalkylene group. The polyoxyalkylene group-containing group is preferably a group represented by Formula (B).

-L-(R¹—O)ₙ—R² Formula (B)

L represents a single bond or a divalent linking group. Examples of the divalent linking group include a hydrocarbon group (for example, an alkylene group or an arylene group), —O—, —S—, —CO—, —SO₂—, —N(R³)—, and a combination thereof. R³ represents a hydrogen atom or an alkyl group.

R¹ represents an alkylene group. The number of carbon atoms in the alkylene group is not particularly limited and is preferably 1 to 5 and more preferably 1 to 3.

n represents an integer of 2 or more and is preferably 2 to 20 and more preferably 3 to 10.

R² represents a hydrogen atom or an alkyl group. The number of carbon atoms in the alkyl group is not particularly limited and is preferably 1 to 20.

The molecular weight of the specific compound contained in the first embodiment of the chemical liquid is preferably 1,000 or less, more preferably 600 or less, and still more preferably 300 or less. The lower limit of the molecular weight is preferably 60 or more.

In a case where the specific compound contains a repeating unit, the molecular weight means a weight-average molecular weight.

At least one (preferably two or more) of the specific compounds contained in the first embodiment of the chemical liquid is preferably a specific compound having a molecular weight within the above-mentioned preferred molecular weight range (for example, 600 or less or 300 or less). It is also preferable that all of the specific compounds contained in the first embodiment of the chemical liquid are specific compounds having a molecular weight within the above-mentioned preferred molecular weight range.

As described above, the first embodiment of the chemical liquid contains two or more specific compounds. Above all, it is preferable to satisfy the following requirement 1 or 2 from the viewpoint that the contact angle is larger.

Requirement 1: The chemical liquid contains a first specific compound having a nitrogen-containing group which is a polar group and a vertical alignment group, and a second specific compound having a polar group other than the nitrogen-containing group and a vertical alignment group.

Requirement 2: The chemical liquid contains two or more third specific compounds having a polar group selected from the group consisting of a nitrogen-containing group, a phosphonate group or a salt thereof, a carboxy group or a salt thereof, and a thiol group, and a vertical alignment group, and the polar groups in the two or more third specific compounds are the same.

In the requirement 1, the first specific compound is preferably a compound represented by Formula (1).

X¹—Y¹ Formula (1)

X¹ represents a nitrogen-containing group, and Y¹ represents a hydrocarbon group which may have a halogen atom or a polyoxyalkylene group-containing group. The nitrogen-containing group represented by X¹ is a polar group, and the hydrocarbon group which may have a halogen atom and the polyoxyalkylene group-containing group, represented by Y¹, are vertical alignment groups.

The nitrogen-containing group represented by X¹ is as described above.

The hydrocarbon group which may have a halogen atom and the polyoxyalkylene group-containing group, represented by Y¹, have the same meaning as the hydrocarbon group which may have a halogen atom and the polyoxyalkylene group-containing group, represented by Y^{a}, respectively.

The second specific compound is preferably a compound represented by Formula (2).

X²—Y² Formula (2)

X² represents a polar group other than a nitrogen-containing group, and Y² represents a hydrocarbon group which may have a halogen atom or a polyoxyalkylene group-containing group. The hydrocarbon group which may have a halogen atom and the polyoxyalkylene group-containing group, represented by Y², are vertical alignment groups.

The polar group other than a nitrogen-containing group represented by X² is a group other than a nitrogen-containing group exemplified in the above-mentioned polar group, and examples thereof include a phosphate group or a salt thereof, a phosphonate group or a salt thereof, a sulfo group or a salt thereof, a carboxy group or a salt thereof, a thiol group, and a hydroxy group.

The hydrocarbon group which may have a halogen atom and the polyoxyalkylene group-containing group, represented by Y², have the same meaning as the hydrocarbon group which may have a halogen atom and the polyoxyalkylene group-containing group, represented by Y^{a}, respectively.

In a case where the first specific compound is a compound represented by Formula (1) and the second specific compound is a compound represented by Formula (2), Y¹ and Y² may be different from each other or may be the same as each other.

In a case where Y¹ and Y² are different from each other, it is preferable that both Y¹ and Y² are hydrocarbon groups which may have a halogen atom, and the difference in the number of carbon atoms between the hydrocarbon groups of Y¹ and Y² is 6 or more.

In a case where the above-mentioned requirement 1 is satisfied, the polar group that the second specific compound has is preferably a phosphonate group or a salt thereof, a carboxy group or a salt thereof, or a thiol group, and more preferably a carboxy group, a phosphonate group, or a thiol group.

In the requirement 1, the proportion of the content of the first specific compound with respect to the total content of the specific compounds is preferably 10% to 90% by mass and more preferably 20% to 80% by mass.

In the requirement 1, the proportion of the content of the second specific compound with respect to the total content of the specific compounds is preferably 10% to 90% by mass and more preferably 20% to 80% by mass.

In the requirement 2, it is preferable that the chemical liquid contains, as the third specific compound, a third specific compound A represented by Formula (3A) and a third specific compound B represented by Formula (3B).

X^{3A}—Y^{3A} Formula (3A)

X^{3A} represents a polar group selected from the group consisting of a nitrogen-containing group, a phosphonate group or a salt thereof, a carboxy group or a salt thereof, and a thiol group, and Y^{3A} represents a hydrocarbon group which may have a halogen atom or a polyoxyalkylene group-containing group. The nitrogen-containing group represented by X^{3A} is as described above. The hydrocarbon group which may have a halogen atom and the polyoxyalkylene group-containing group, represented by Y^{3A}, are vertical alignment groups.

The hydrocarbon group which may have a halogen atom and the polyoxyalkylene group-containing group, represented by Y^{3A}, have the same meaning as the hydrocarbon group which may have a halogen atom and the polyoxyalkylene group-containing group, represented by Y^{a}, respectively.

X^{3B}—Y^{3B} Formula (3B)

X^{3B} represents a polar group selected from the group consisting of a nitrogen-containing group, a phosphonate group or a salt thereof, a carboxy group or a salt thereof, and a thiol group, and Y^{3B} represents a hydrocarbon group which may have a halogen atom or a polyoxyalkylene group-containing group. The nitrogen-containing group represented by X^{3B} is as described above. The hydrocarbon group which may have a halogen atom and the polyoxyalkylene group-containing group, represented by Y^{3B}, are vertical alignment groups.

The hydrocarbon group which may have a halogen atom and the polyoxyalkylene group-containing group, represented by Y^{3B}, have the same meaning as the hydrocarbon group which may have a halogen atom and the polyoxyalkylene group-containing group, represented by Y^{a}, respectively.

In a case where the above-mentioned requirement 2 is satisfied, the polar groups that the third specific compounds have are the same. That is, in a case where the chemical liquid contains the third specific compound A represented by Formula (3A) and the third specific compound B represented by Formula (3B), X^{3A} and X^{3B} are the same, and Y^{3A} and Y^{3B} are different from each other.

In a case where Y^{3A} and Y^{3B} are different from each other, it is preferable that both Y^{3A} and Y^{3B} are hydrocarbon groups which may have a halogen atom, and the difference in the number of carbon atoms between the hydrocarbon groups of Y^{3A} and Y^{3B} is 6 or more.

In the requirement 2, the proportion of the content of the third specific compound A with respect to the total content of the specific compounds is preferably 10% to 90% by mass and more preferably 20% to 80% by mass.

In the requirement 2, the proportion of the content of the third specific compound B with respect to the total content of the specific compounds is preferably 10% to 90% by mass and more preferably 20% to 80% by mass.

In addition, in a case where the number of carbon atoms in the vertical alignment group in the third specific compound A (preferably, the number of carbon atoms in the hydrocarbon group which may have a halogen atom represented by Y^{3A} in Formula (3A)) is larger than the number of carbon atoms in the vertical alignment group in the third specific compound B (preferably, the number of carbon atoms in the hydrocarbon group which may have a halogen atom represented by Y^{3B} in Formula (3B)), it is also preferable that the proportion of the content of the third specific compound A with respect to the total content of the specific compounds is 10% to 30% by mass.

In the first embodiment of the chemical liquid, the content of the specific compound is preferably 0.01% to 10.0% by mass, more preferably 0.1% to 5.0% by mass, and still more preferably 0.5% to 3.0% by mass with respect to the total mass of the chemical liquid.

### [Other Components]

The first embodiment of the chemical liquid may contain other components in addition to the components described above.

Examples of other components include a polymer. Examples of the polymer include an acrylic polymer, a siloxane-based polymer, and a styrene-based polymer.

Specific examples of the polymer include the polymers described in paragraphs to of JP2021-041364A.

### Second Embodiment of Chemical Liquid

The second embodiment of the chemical liquid according to the embodiment of the present invention contains a solvent and two or more specific compounds.

In addition, as described above, the specific compound is the compound 2.

The aspect (type, content, or the like) of the solvent contained in the second embodiment of the chemical liquid is the same as the aspect of the solvent contained in the first embodiment of the chemical liquid, so the description thereof will not be repeated.

### [Specific Compound]

The second embodiment of the chemical liquid according to the embodiment of the present invention contains two or more specific compounds. Examples of the specific compound include the compound 2.

The expression that the chemical liquid contains two or more specific compounds means that the chemical liquid contains two or more specific compounds different in structure. Different in structure means that the structures of two specific compounds are not the same and include, for example, that the types of polar groups in the two specific compounds are different from each other, and that the types of specific groups in the two specific compounds are different from each other.

The type of polar group in the specific compound contained in the second embodiment of the chemical liquid is the same as the type of polar group in the specific compound contained in the first embodiment of the chemical liquid, so the description thereof will not be repeated.

The specific compound contained in the second embodiment of the chemical liquid has a specific group selected from the group consisting of a hydrocarbon group which may have a halogen atom and a polyoxyalkylene group.

The definition and suitable aspect of the hydrocarbon group which may have a halogen atom are the same as the definition and suitable aspect of the hydrocarbon group which may have a halogen atom, which is an example of the vertical alignment group that the above-mentioned specific compound has, so the description thereof will not be repeated.

The definition and suitable aspect of the polyoxyalkylene group are the same as the definition and suitable aspect of the polyoxyalkylene group which is an example of the vertical alignment group that the above-mentioned specific compound has, so the description thereof will not be repeated.

The specific compound contained in the second embodiment of the chemical liquid is preferably a compound represented by Formula (C).

X^{c}—Y^{c} Formula (C)

X^{c} represents a polar group and Ye represents a hydrocarbon group which may have a halogen atom or a polyoxyalkylene group-containing group.

The polar group represented by X^{c} is as described above.

The hydrocarbon group which may have a halogen atom, represented by Ye, is as described above.

The definition and suitable aspect of the polyoxyalkylene group-containing group represented by Ye are the same as the definition and suitable aspect of the polyoxyalkylene group-containing group represented by Y^{a}, so the description thereof will not be repeated.

The molecular weight of the specific compound contained in the second embodiment of the chemical liquid is preferably 1,000 or less, more preferably 600 or less, and still more preferably 300 or less. The lower limit of the molecular weight is preferably 60 or more.

In a case where the specific compound contains a repeating unit, the molecular weight means a weight-average molecular weight.

At least one (preferably two or more) of the specific compounds contained in the second embodiment of the chemical liquid is preferably a specific compound having a molecular weight within the above-mentioned preferred molecular weight range (for example, 600 or less or 300 or less). It is also preferable that all of the specific compounds contained in the second embodiment of the chemical liquid are specific compounds having a molecular weight within the above-mentioned preferred molecular weight range.

As described above, the second embodiment of the chemical liquid contains two or more specific compounds. Above all, it is preferable to satisfy the following requirement 1 or 2 from the viewpoint that the contact angle is larger.

Requirement 3: The chemical liquid contains a fourth specific compound having a nitrogen-containing group which is a polar group and a specific group, and a fifth specific compound having a polar group other than the nitrogen-containing group and a specific group.

Requirement 4: The chemical liquid contains two or more sixth specific compounds having a polar group selected from the group consisting of a nitrogen-containing group, a phosphonate group or a salt thereof, a carboxy group or a salt thereof, and a thiol group, and a specific group, and the polar groups in the two or more sixth specific compounds are the same.

In the requirement 3, the fourth specific compound is preferably a compound represented by Formula (4).

X⁴—Y⁴ Formula (4)

X⁴ represents a nitrogen-containing group, and Y⁴ represents a hydrocarbon group which may have a halogen atom or a polyoxyalkylene group-containing group.

The nitrogen-containing group represented by X⁴ is as described above.

The hydrocarbon group which may have a halogen atom and the polyoxyalkylene group-containing group, represented by Y⁴, have the same meaning as the hydrocarbon group which may have a halogen atom and the polyoxyalkylene group-containing group, represented by Y^{a}, respectively.

The fifth specific compound is preferably a compound represented by Formula (5).

X⁵—Y⁵ Formula (5)

X⁵ represents a polar group other than a nitrogen-containing group, and Y⁵ represents a hydrocarbon group which may have a halogen atom or a polyoxyalkylene group-containing group.

The polar group other than a nitrogen-containing group represented by X⁵ is a group other than a nitrogen-containing group exemplified in the above-mentioned polar group, and examples thereof include a phosphate group or a salt thereof, a phosphonate group or a salt thereof, a sulfo group or a salt thereof, a carboxy group or a salt thereof, a thiol group, and a hydroxy group.

The hydrocarbon group which may have a halogen atom and the polyoxyalkylene group-containing group, represented by Y⁵, have the same meaning as the hydrocarbon group which may have a halogen atom and the polyoxyalkylene group-containing group, represented by Y^{a}, respectively.

In a case where the fourth specific compound is a compound represented by Formula (4) and the fifth specific compound is a compound represented by Formula (5), Y⁴ and Y⁵ may be different from each other or may be the same as each other.

In a case where Y⁴ and Y⁵ are different from each other, it is preferable that both Y⁴ and Y⁵ are hydrocarbon groups which may have a halogen atom, and the difference in the number of carbon atoms between the hydrocarbon groups of Y⁴ and Y⁵ is 6 or more.

In a case where the above-mentioned requirement 3 is satisfied, the polar group that the fifth specific compound has is preferably a phosphonate group or a salt thereof, a carboxy group or a salt thereof, or a thiol group, and more preferably a carboxy group, a phosphonate group, or a thiol group.

In the requirement 3, the proportion of the content of the fourth specific compound with respect to the total content of the specific compounds is preferably 10% to 90% by mass and more preferably 20% to 80% by mass.

In the requirement 3, the proportion of the content of the fifth specific compound with respect to the total content of the specific compounds is preferably 10% to 90% by mass and more preferably 20% to 80% by mass.

In the requirement 4, it is preferable that the chemical liquid contains, as the sixth specific compound, a sixth specific compound A represented by Formula (6A) and a sixth specific compound B represented by Formula (6B).

X^{6A}—Y^{6A} Formula (6A)

X^{6A} represents a polar group selected from the group consisting of a nitrogen-containing group, a phosphonate group or a salt thereof, a carboxy group or a salt thereof, and a thiol group, and Y^{6A} represents a hydrocarbon group which may have a halogen atom or a polyoxyalkylene group-containing group. The nitrogen-containing group represented by X^{6A} is as described above. The hydrocarbon group which may have a halogen atom and the polyoxyalkylene group-containing group, represented by Y^{6A}, are specific groups.

The hydrocarbon group which may have a halogen atom and the polyoxyalkylene group-containing group, represented by Y^{6A}, have the same meaning as the hydrocarbon group which may have a halogen atom and the polyoxyalkylene group-containing group, represented by Y^{a}, respectively.

X^{6B}—Y^{6B} Formula (6B)

X^{6B} represents a polar group selected from the group consisting of a nitrogen-containing group, a phosphonate group or a salt thereof, a carboxy group or a salt thereof, and a thiol group, and Y^{6B} represents a hydrocarbon group which may have a halogen atom or a polyoxyalkylene group-containing group. The nitrogen-containing group represented by X^{6B} is as described above. The hydrocarbon group which may have a halogen atom and the polyoxyalkylene group-containing group, represented by Y^{6B}, are specific groups.

The hydrocarbon group which may have a halogen atom and the polyoxyalkylene group-containing group, represented by Y^{6B}, have the same meaning as the hydrocarbon group which may have a halogen atom and the polyoxyalkylene group-containing group, represented by Y^{a}, respectively.

In a case where the above-mentioned requirement 4 is satisfied, the polar groups that the sixth specific compounds have are the same. That is, in a case where the chemical liquid contains the sixth specific compound A represented by Formula (6A) and the sixth specific compound B represented by Formula (6B), X^{6A} and X^{6B} are the same, and Y^{6A} and Y^{6B} are different from each other.

In a case where Y^{6A} and Y^{6B} are different from each other, it is preferable that both Y^{6A} and Y^{6B} are hydrocarbon groups which may have a halogen atom, and the difference in the number of carbon atoms between the hydrocarbon groups of Y^{6A} and Y^{6B} is 6 or more.

In the requirement 4, the proportion of the content of the sixth specific compound A with respect to the total content of the specific compounds is preferably 10% to 90% by mass and more preferably 20% to 80% by mass.

In the requirement 4, the proportion of the content of the sixth specific compound B with respect to the total content of the specific compounds is preferably 10% to 90% by mass and more preferably 20% to 80% by mass.

In addition, in a case where the number of carbon atoms in the specific group in the sixth specific compound A (preferably, the number of carbon atoms in the hydrocarbon group which may have a halogen atom represented by Y^{6A} in Formula (6A)) is larger than the number of carbon atoms in the specific group in the sixth specific compound B (preferably, the number of carbon atoms in the hydrocarbon group which may have a halogen atom represented by Y^{6B} in Formula (6B)), it is also preferable that the proportion of the content of the sixth specific compound A with respect to the total content of the specific compounds is 10% to 30% by mass.

In the second embodiment of the chemical liquid, the content of the specific compound is preferably 0.01% to 10.0% by mass, more preferably 0.1% to 5.0% by mass, and still more preferably 0.5% to 3.0% by mass with respect to the total mass of the chemical liquid.

### [Other Components]

The second embodiment of the chemical liquid may contain other components in addition to the components described above.

Examples of other components include a polymer. Examples of the polymer include an acrylic polymer, a siloxane-based polymer, and a styrene-based polymer.

Specific examples of the polymer include the polymers described in paragraphs to of JP2021-041364A.

### <Manufacturing Method of Chemical Liquid>

The manufacturing method of the chemical liquid according to the embodiment of the present invention (first embodiment and second embodiment) is not particularly limited, and the chemical liquid can be manufactured, for example, by mixing the above-mentioned components. The order or timing of mixing each component and the order and timing of mixing each component are not particularly limited. For example, a method of manufacturing a chemical liquid by adding two or more specific compounds to a stirrer such as a mixing mixer containing a purified solvent, and then sufficiently stirring the mixture can be mentioned.

In the manufacturing process of manufacturing the chemical liquid according to the embodiment of the present invention, the steps described below may be carried out.

### [Metal Removal Step]

In the above-mentioned manufacturing method, a metal removal step of removing a metal component from the above-mentioned components and/or chemical liquid (hereinafter, also referred to as “substance to be purified”) may be carried out.

Examples of the metal removal step include a step P in which the substance to be purified is subjected to an ion exchange method.

### (Step P)

In the step P, the above-mentioned substance to be purified is subjected to an ion exchange method.

The ion exchange method is not particularly limited as long as it is a method that can adjust (reduce) the amount of metal components in the substance to be purified. From the viewpoint of more easily manufacturing the chemical liquid, the ion exchange method preferably includes one or more of the following methods P1 to P3. The ion exchange method more preferably includes two or more of the methods P1 to P3, and still more preferably includes all of the methods P1 to P3. In a case where the ion exchange method includes all of the methods P1 to P3, the methods may be carried out in any order without particular limitation, but it is preferable to carry out the methods P1 to P3 in this order.
Method P1: a method of passing the substance to be purified through a first filling portion filled with a mixed resin including two or more resins selected from the group consisting of a cation exchange resin, an anion exchange resin, and a chelating resin.
Method P2: a method of passing the substance to be purified through at least one filling portion of a second filling portion filled with a cation exchange resin, a third filling portion filled with an anion exchange resin, or a fourth filling portion filled with a chelating resin.
Method P3: a method of passing the substance to be purified through a membrane-like ion exchanger.

In a case where the ion exchange resins (the cation exchange resin and the anion exchange resin), the chelating resin, and the membrane-like ion exchanger used in each of the methods are in forms other than H form or OH form, it is preferable to use the resins and the ion exchanger after being regenerated into H form or OH-form.

In addition, the space velocity (SV) of the substance to be purified in each of the methods is preferably 0.01 to 20.0 (1/h) and more preferably 0.1 to 10.0 (1/h).

In addition, the treatment temperature in each of the methods is preferably 0° C. to 60° C. and more preferably 10° C. to 50° C.

In addition, examples of the form of the ion exchange resin and chelating resin include a granular form, a fibrous form, and a porous monolithic form, among which a granular form or a fibrous form is preferable.

The average particle diameter of the granular ion exchange resin and chelating resin is preferably 10 to 2,000 μm and more preferably 100 to 1,000 μm.

As for the particle size distribution of the granular ion exchange resin and chelating resin, it is preferable that the abundance ratio of resin particles having a size in a range of average particle diameter ±200 μm is 90% or more.

The average particle diameter and the particle size distribution may be measured, for example, using a particle size distribution analyzer (Microtrac HRA3920, manufactured by Nikkiso Co., Ltd.) and using water as a dispersion medium.

The ion exchange method is preferably carried out until the content of the metal component contained in the substance to be purified falls into the above-mentioned preferred range of the metal component content.

### [Filtration Step]

The above-mentioned manufacturing method preferably includes a filtration step of filtering a liquid in order to remove foreign substances, coarse particles, and the like from the liquid.

The filtration method is not particularly limited, and a known filtration method can be used. Above all, filtering using a filter is preferable.

Any filter that is used for filtering can be used without particular limitation, as long as it is a filter that has been used in the related art for filtration or the like. Examples of the material constituting the filter include a fluororesin such as polytetrafluoroethylene (PTFE), a polyamide-based resin such as nylon, a polyolefin-based resin (including a high density, ultrahigh-molecular-weight polyolefin-based resin) such as polyethylene or polypropylene (PP), and polyarylsulfone. Above all, a polyamide-based resin, PTFE, polypropylene (including high density polypropylene), and polyarylsulfone are preferable.

The lower limit value of the critical surface tension of the filter is preferably 70 mN/m or more, and the upper limit value of the critical surface tension of the filter is preferably 95 mN/m or less. In particular, the critical surface tension of the filter is preferably 75 to 85 mN/m.

It is noted that the value of the critical surface tension is a nominal value of a manufacturer.

The pore diameter of the filter is preferably about 0.001 to 1.0 μm, more preferably about 0.02 to 0.5 μm, and still more preferably about 0.01 to 0.1 μm. In a case where the pore diameter of the filter is in the above range, it is possible to reliably remove fine foreign substances contained in the substance to be purified while suppressing filter clogging.

In a case of using the filter, different filters may be combined. At this time, filtering using a first filter may be carried out only once, or may be carried out two or more times. In a case where filtering is carried out two or more times by combining different filters, the filters may be of the same type or different types, but it is preferable that the filters are of different types. Typically, it is preferable that the first filter and the second filter differ from each other in at least one of the pore diameter or the constituent material.

It is preferable that the pore diameters in the second filtering and the subsequent filtering are equal to or smaller than the pore diameter in the first filtering. In addition, the first filters having different pore diameters within the above range may be combined. With regard to the pore diameter of the filter herein, reference can be made to a nominal value of the filter manufacturer.

### [Static Neutralization Step]

The manufacturing method of the chemical liquid may further include a static neutralization step of statically neutralizing the chemical liquid.

### [Container]

For example, a known container can be used as the container for accommodating the chemical liquid.

The container is preferably a container for semiconductor applications which has a high degree of internal cleanliness and has a low elution of impurities.

Examples of the container include “CLEAN BOTTLE” series (manufactured by Aicello Chemical Co., Ltd.) and “PURE BOTTLE” (manufactured by Kodama Plastics Co., Ltd.). In addition, from the viewpoint of preventing the incorporation of impurities (contamination) into the raw materials and the chemical liquid, it is also preferable to use a multi-layer container in which an interior wall of the container has a six-layer structure consisting of six types of resins, or a multi-layer container in which an interior wall of the container has a seven-layer structure consisting of seven types of resins.

Examples of the multi-layer container include the containers described in JP2015-123351A, the contents of which are incorporated herein by reference.

Examples of materials for the interior wall of the container include a first resin of at least one selected from the group consisting of a polyethylene resin, a polypropylene resin, and a polyethylene-polypropylene resin, a second resin different from the first resin, and a metal such as stainless steel, Hastelloy, Inconel, or Monel. In addition, it is preferable that the interior wall of the container is formed of or coated with the above-mentioned materials.

The second resin is preferably a fluororesin (perfluororesin).

In a case where a fluororesin is used, elution of an oligomer of ethylene or propylene can be suppressed.

Examples of the container include a FluoroPure PFA composite drum (manufactured by Entegris, Inc.), and the containers described on page 4 of JP1991-502677A (JP-H-03-502677A), page 3 of WO2004/016526A, and pages 9 and 16 of WO99/046309A.

In addition to the fluororesin, for example, quartz and an electropolished metal material (a metal material subjected to electropolishing) are also preferable for the interior wall of the container.

The metal material used for the electropolished metal material is preferably a metal material containing at least one selected from the group consisting of chromium (Cr) and nickel (Ni), in which the total content of Cr and Ni is more than 25% by mass with respect to the total mass of the metal material. Examples of such a metal material include stainless steel and a Ni—Cr alloy.

The total content of Cr and Ni in the metal material is preferably 25% by mass or more and more preferably 30% by mass or more with respect to the total mass of the metal material. The upper limit of the total content of Cr and Ni is preferably 90% by mass or less with respect to the total mass of the metal material.

Examples of the stainless steel include known stainless steel.

Above all, stainless steel containing 8% by mass or more of Ni is preferable, and austenitic stainless steel containing 8% by mass or more of Ni is more preferable.

Examples of the Ni—Cr alloy include known Ni—Cr alloys.

Above all, a Ni—Cr alloy having a Ni content of 40% to 75% by mass and a Cr content of 1% to 30% by mass is preferable.

The Ni—Cr alloy may further contain boron, silicon, tungsten, molybdenum, copper, or cobalt in addition to the above-mentioned components, if necessary.

Examples of the method for electropolishing a metal material include known methods.

Specific examples of the method for electropolishing a metal material include the methods described in paragraphs to of JP2015-227501A, the contents of which are incorporated herein by reference and the methods described in paragraphs to of JP2008-264929A, the contents of which are incorporated herein by reference.

The metal material is preferably subjected to buffing.

Examples of the buffing method include known methods.

The size of abrasive grains used for finishing the buffing is preferably #400 or less from the viewpoint that surface asperities of the metal material are likely to be further reduced. The buffing is preferably carried out before the electropolishing.

The metal material may be subjected to one of multi-stage buffing that is carried out by changing the size or the like of the abrasive grains, acid washing, magnetorheological finishing, and the like, or a combination of two or more thereof.

It is preferable to clean the inside of the container before being filled with the chemical liquid.

The liquid used for cleaning can be appropriately selected depending on the intended use, and is preferably a liquid containing the chemical liquid or at least one of the components added to the chemical liquid.

The inside of the container may be purged with an inert gas (for example, nitrogen or argon) having a purity of 99.99995% by volume or higher from the viewpoint of preventing changes in the components of the chemical liquid during storage. In particular, a gas having a low moisture content is preferable. In addition, transportation and storage of the container accommodating the chemical liquid may be carried out either at normal temperature or under temperature control. Above all, from the viewpoint of preventing deterioration, it is preferable to control the temperature in a range of −20° C. to 20° C.

### <Applications of Chemical Liquid>

The chemical liquid according to the embodiment of the present invention is preferably used for treating a substrate having a metal region.

As the method for treating a substrate, the chemical liquid according to the embodiment of the present invention may be brought into contact with a substrate having a metal region. By the above-mentioned treatment, a modified substrate is obtained in which a film containing two or more specific compounds contained in the chemical liquid according to the embodiment of the present invention (high contact angle film) is formed on the substrate having a metal region. The manufacturing method of the modified substrate will be described later.

The substrate having a metal region is a substrate having a metal region and the other region. The metal region refers to a region where the surface is composed of a metal, and the other region refers to a region where the surface is composed of a material other than the metal. The metal constituting the metal region is not particularly limited, and is preferably a transition metal, more preferably a Group 6 to Group 11 element, still more preferably a Group 6 element, a Group 8 element, a Group 9 element, or a Group 11 element, and particularly preferably ruthenium or tungsten. The metal constituting the metal region may be an alloy containing the above-mentioned metal. Examples of the material constituting the other region include an insulator, and examples of the insulator include an oxide (for example, a metal oxide, a metal nitride, or SiO₂).

The substrate having a metal region is also preferably a semiconductor substrate having a metal region.

By the above-mentioned treatment, it is preferable that a high contact angle film is formed on the substrate having a metal region, and it is more preferable that a high contact angle film is formed only on the metal region.

It is preferable that the high contact angle film functions as a mask in a case where a film is formed on a substrate having a metal region by chemical vapor deposition (CVD). In other words, it is preferable that a film by CVD (hereinafter, also referred to as a “CVD film”) is difficult to deposit in a region where the high contact angle film formed of the chemical liquid according to the embodiment of the present invention is formed, and the CVD film is deposited in a region where the high contact angle film is not formed. In a case where the high contact angle film functions as a mask for CVD, a laminate in which the CVD film is selectively formed on the other region on the substrate can be obtained. The manufacturing method of the laminate will be described later.

The contact angle of the high contact angle film is preferably 60° or more, more preferably 90° or more, and still more preferably 105° or more from the viewpoint that the high contact angle film easily functions as a mask for CVD. The upper limit of the contact angle is not particularly limited and is often 120° or less.

### <Manufacturing Method of Modified Substrate>

It is preferable that the modified substrate including a high contact angle film is manufactured by bringing the chemical liquid according to the embodiment of the present invention into contact with a substrate having a metal region. It is preferable that the high contact angle film is formed only in the metal region. In addition, it is more preferable that the high contact angle film functions as a mask for CVD. The modified substrate of the more preferred aspect can be suitably applied to the manufacture of a laminate.

The contact method is not particularly limited, and examples thereof include a method of applying or spraying the chemical liquid onto a substrate having a metal region and a method of immersing a substrate having a metal region in the chemical liquid. The method of applying the chemical liquid onto the substrate is not particularly limited, and any known method can be used, such as spin coating. In addition, in a case where the substrate is immersed in the chemical liquid, the chemical liquid may be subjected to convection.

The temperature during the contact is not particularly limited and is preferably 10° C. to 50° C.

In addition, it is also preferable to heat the substrate after bringing the chemical liquid into contact with the substrate having a metal region. The solvent contained in the chemical liquid can be removed by heating, so that the film containing the specific compound can be made denser.

The heating temperature is not particularly limited, and is preferably 50° C. to 300° C. and more preferably 60° C. to 180° C.

The heating method is not particularly limited, and examples thereof include a method of being brought into contact with a heating element (for example, heating with a hot plate) and a method of irradiation with infrared rays.

In addition, it is also preferable to subject the heated substrate to a rinsing treatment. The specific compound on the substrate which has adhered to a region other than a desired region can be removed from the substrate by the rinsing treatment.

The rinsing method is not particularly limited, and examples thereof include a method of bringing a rinsing liquid into contact with the heated substrate. Examples of the contact method include the same method as the method of bringing the chemical liquid into contact with a substrate having a metal region. The temperature during the contact is not particularly limited and is preferably 10° C. to 50° C.

The rinsing liquid is not particularly limited, and examples thereof include the solvent contained in the chemical liquid according to the embodiment of the present invention. The solvent contained in the chemical liquid used to form the high contact angle film may be used as the rinsing liquid.

### <Manufacturing Method of Laminate>

In a case where the CVD treatment is carried out using the modified substrate, a laminate is obtained in which the CVD film is formed on the region where the high contact angle film is not formed (on the region other than the metal region).

The CVD treatment may be carried out by a known method, among which thermal CVD, plasma CVD, or atomic layer deposition (ALD) is preferable and ALD is more preferable.

In the CVD treatment, a precursor serving as a raw material of the CVD film is supplied to the surface of the modified substrate. The material constituting the CVD film to be formed can be controlled by the type of precursor supplied, the supply atmosphere, the oxidant, and the like. The material for the CVD film to be formed is not particularly limited, and examples thereof include a metal, a metal oxide, and a metal nitride. Examples of the metal include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth. Examples of the metal oxide include aluminum oxide, titanium oxide, zinc oxide, zirconium oxide, hafnium oxide, and tantalum oxide. Examples of the metal nitride include titanium nitride and tantalum nitride.

In the CVD treatment, a treatment to alter the surface of the region where the high contact angle film is not formed may be carried out.

In a case where a CVD film is formed on the region where the high contact angle film is not formed by the CVD treatment, a ratio of the thickness of the CVD film on the region where the high contact angle film is formed to the thickness of the CVD film on the region where the high contact angle film is not formed is preferably 0.75 or less, more preferably 0.5 or less, and still more preferably 0.25 or less. The lower limit of the ratio is, for example, 0, and may be 0. That is, the CVD film may not be formed on the region where the high contact angle film is formed.

In the laminate obtained by the above-mentioned method, the high contact angle film may be further removed. In a case where the high contact angle film is removed, a laminate in which the CVD film is formed only on a region other than the metal region can be obtained.

The method of removing the high contact angle film is not particularly limited, and examples thereof include dry etching, wet etching, and a combination thereof.

Examples of the dry etching include a method of supplying reactive ions or reactive radicals to the surface of the laminate having a high contact angle film. The reactive ions or the reactive radicals may be generated by plasma or the like, and are preferably generated using a mixed gas containing one or more gases selected from the group consisting of oxygen, nitrogen, and hydrogen. The mixed gas may contain a rare gas. In addition, the dry etching may be physical etching using a sputtering phenomenon.

In the wet etching, the etchant may be supplied to the surface of the laminate having a high contact angle film. Examples of the etchant include an etchant containing an oxidant such as ozone and an etchant containing an organic solvent. Examples of the organic solvent in the etchant containing an organic solvent include the organic solvent contained in the above-mentioned chemical liquid, among which a hydrocarbon-based solvent is preferable.

### EXAMPLES

Hereinafter, the present invention will be described in more detail with reference to Examples.

The materials, amounts of materials used, proportions, treatment details, treatment procedure, and the like shown in Examples given below can be appropriately modified without departing from the spirit and scope of the present invention. Accordingly, the scope of the present invention should not be construed as being limited to the Examples described below.

### <Preparation of Chemical Liquid>

The chemical liquids used in Examples and Comparative Examples were prepared by mixing components at the proportions shown in the table which will be given later.

The preparation, filling, storage, and the like of the chemical liquid were all carried out in a clean room satisfying a level equal to or lower than ISO Class 2. In addition, the container used for the preparation, filling, storage, and the like of the chemical liquid was used after being cleaned with the solvent used for the preparation or the prepared chemical liquid.

### <Evaluation Method>

According to the following procedure, a film containing two or more specific compounds (high contact angle film) was formed on a substrate using each of chemical liquids of Examples and Comparative Examples, and the contact angle of water in the film was evaluated. In addition, a formation treatment of an oxide film by ALD was carried out on the substrate on which the high contact angle film was formed, and the deposition selectivity was evaluated from the thickness of the formed oxide film.

### [Evaluation of Contact Angle]

First, a W layer wafer with a tungsten layer formed by CVD on one surface of a commercially available silicon wafer (12 inches in diameter), and a Ru layer wafer with a ruthenium layer formed by CVD on one surface of a commercially available silicon wafer (12 inches in diameter) were prepared as substrates. The CVD treatment time was adjusted so that the thickness of each of the tungsten layer and the ruthenium layer was 20 nm.

The obtained W layer wafer and Ru layer wafer were cut into 2 cm square pieces and each cut wafer was immersed in each chemical liquid. Each wafer was immersed in the chemical liquid while stirring the chemical liquid placed in a container under the condition of 250 rpm using a magnetic stirrer. The temperature of the chemical liquid was 25° C., and the immersion time was 10 minutes.

Regarding the W layer wafer, the above immersion was carried out after carrying out the following pretreatment.

The W layer wafer was immersed in a 1% by mass citric acid aqueous solution. The immersion in the citric acid aqueous solution was carried out while stirring the chemical liquid placed in a container under the condition of 250 rpm using a magnetic stirrer. The temperature of the chemical liquid was 25° C., and the immersion time was 1 minute. After the immersion, the W layer wafer was dried by blowing nitrogen gas.

Next, each wafer that had been immersed in the chemical liquid was subjected to a heating treatment. The heating treatment was carried out using a hot plate, the heating temperature was 120° C., and the heating time was 5 minutes.

After the heating treatment, the temperature of each wafer was set to 25° C. and then a rinsing treatment was carried out with isopropyl alcohol (IPA). The rinsing treatment was carried out by immersing the substrate after the heating treatment in IPA. The immersion was carried out while stirring IPA placed in a container with a magnetic stirrer under the condition of 250 rpm, the temperature of IPA was 25° C., and the immersion time was 30 seconds.

After the rinsing treatment, each wafer was dried by blowing nitrogen gas.

Through the above-mentioned treatment, a high contact angle film was formed on each wafer and a sample was obtained.

The contact angle of water in the sample obtained by the above-mentioned method was measured by the following method.

The measurement was carried out in an environment of 23° C. using DMs-501 (manufactured by Kyowa Interface Science Co., Ltd.). The value 500 milliseconds after the liquid droplet of water came into contact with the surface was measured three times, and an average value of the measured values was taken as the contact angle. The analysis was carried out with a surface tension of water being 72.9 mN/m.

Based on the contact angle obtained in the above measurement, the contact angle was evaluated according to the following standards. An evaluation of B or higher is preferable in terms of practical use.
AA: The contact angle of water is 105° or more
A: The contact angle of water is 90° or more and less than 105°.
B: The contact angle of water is 60° or more and less than 90°
C: The contact angle of water is less than 60°

### [Evaluation of Deposition Selectivity]

A sample was obtained in the same manner as in the case of the contact angle described above, and subjected to an ALD treatment according to the following procedure to evaluate deposition selectivity.

First, an aluminum oxide layer was formed on the obtained sample using an atomic layer deposition system (AD-230LP, manufactured by Samco Inc.). Trimethyl aluminum was used as an organic metal raw material, and water was used as an oxidant. It is noted that the ALD treatment temperature was 150° C., and each sample was subjected to the ALD treatment under the condition such that the film thickness was 5 nm for each wafer in a case where a high contact angle film was not formed.

The film thickness of the aluminum oxide layer of each sample after the ALD treatment was measured using a spectroscopic ellipsometer (M-2000XI, manufactured by J. A. Woollam Japan, Co., Inc.). The film thickness was measured at 5 points of the sample, and an arithmetic average value of the measured values was taken as the film thickness. The measurement was carried out with a measurement range of 1.2 to 2.5 eV and a measurement angle of 70° and 75°.

It is noted that the smaller the film thickness, the more difficult it is for the film to be deposited by the ALD treatment.

### <Results>

Table 1 shows the components of the chemical liquid and the proportions thereof, the results of evaluating the contact angle, and the results of evaluating deposition selectivity.

The names of the compounds in Table 1 are as follows.

### [Specific Compound]

A-1: octadecylamine
A-2: dodecylamine
A-3: decylamine
A-4: butylamine
A-5: propylamine
B-1: octadecanoic acid
B-2: dodecanoic acid
C-1: octadecyl phosphonate
C-2: dodecyl phosphonate
D-1: octadodecanol
D-2: dodecanol
E-1: octadecanethiol
E-2: decanethiol
F-1: a compound shown below (molecular weight: 502.82)

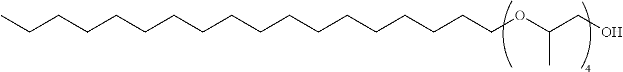

F-2: a compound shown below (molecular weight: 677.06)

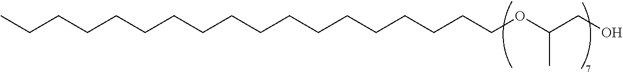

F-3: a compound shown below (molecular weight: 793.22)

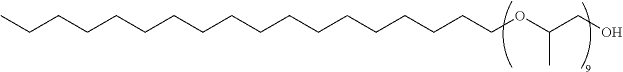

### [Other Compounds]

G-1: octadecane
G-2: decane
H-1: a polymer having the following structure, described in paragraphs and of JP2021-041364A

The polymer having the following structure was synthesized according to the method described in paragraph of JP2021-041364A. The synthesized polymer having the following structure had a weight-average molecular weight of 6,000 and a number-average molecular weight of 5,600.

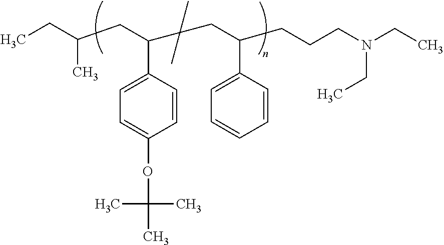

H-2: a polymer having the following structure, described in paragraphs [0170] and [0171] of JP2021-041364A

The polymer having the following structure was synthesized according to the method described in paragraph of JP2021-041364A. The synthesized polymer having the following structure had a weight-average molecular weight of 6,000 and a number-average molecular weight of 5,600.

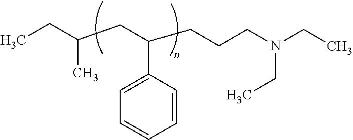

H-3: a polymer having the following structure, described in paragraphs and of JP2021-041364A

The polymer having the following structure was synthesized according to the method described in paragraph of JP2021-041364A. The synthesized polymer having the following structure had a weight-average molecular weight of 5,100 and a number-average molecular weight of 4,800.

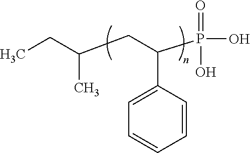

### [Solvent]

S-1: methyl isobutyl carbinol
S-2: isopropyl alcohol

TABLE 1

| | | | Examples | | | | | | | | | | | | |
|---|---|---|---|---|---|---|---|---|---|---|---|---|---|---|---|
| | | | 1 | 2 | 3 | 4 | 5 | 6 | 7 | 8 | 9 | 10 | 11 | 12 | 13 |
| Chemical | Specific | A-1 | 0.5 | 0.75 | 0.4 | 0.25 | 0.5 | | | | | 0.5 | 0.5 | | 0.5 |
| liquid | compound | A-2 | 0.5 | 0.25 | 0.3 | 0.75 | | 0.5 | | | | | | | |
| | (parts | A-3 | | | 0.3 | | | | | | | | | | |
| | by mass) | A-4 | | | | | | | | | 0.5 | | | | |
| | | A-5 | | | | | | | | | 0.5 | | | | |
| | | B-1 | | | | | 0.5 | 0.5 | | | | | | | |
| | | B-2 | | | | | | | | | | | | | |
| | Other | C-1 | | | | | | | 0.5 | | | 0.5 | | | |
| | compounds | C-2 | | | | | | | 0.5 | | | | | | |
| | (parts | D-1 | | | | | | | | 0.5 | | | 0.5 | | |
| | by mass) | D-2 | | | | | | | | 0.5 | | | | | |
| | | E-1 | | | | | | | | | | | | 0.5 | |
| | | E-2 | | | | | | | | | | | | 0.5 | 0.5 |
| | | F-1 | | | | | | | | | | | | | |
| | | F-2 | | | | | | | | | | | | | |
| | | F-3 | | | | | | | | | | | | | |
| | | G-1 | | | | | | | | | | | | | |
| | | G-2 | | | | | | | | | | | | | |
| | | H-1 | | | | | | | | | | | | | |
| | | H-2 | | | | | | | | | | | | | |
| | | H-3 | | | | | | | | | | | | | |
| | Solvent | S-1 | 99.0 | 99.0 | 99.0 | 99.0 | 99.0 | 99.0 | 99.0 | 99.0 | 99.0 | 99.0 | 99.0 | 99.0 | 99.0 |
| | (parts | S-2 | | | | | | | | | | | | | |
| | by mass) | | | | | | | | | | | | | | |
| Evaluation | W layer | Contact angle (°) | 100 | 109 | 111 | 108 | 110 | 110 | 111 | 60 | 60 | 110 | 85 | 110 | 107 |
| | wafer | Evaluation of | A | AA | AA | AA | AA | AA | AA | B | B | AA | B | AA | AA |
| | | contact angle | | | | | | | | | | | | | |
| | | AlOx thickness (nm) | 2.3 | 0.9 | 0.7 | 0.8 | 0.7 | 0.7 | 0.6 | 3.1 | 3.0 | 0.7 | 2.5 | 0.7 | 0.9 |
| | Ru layer | Contact angle (°) | 90 | 91 | 90 | 108 | 110 | 111 | 100 | 70 | 81 | 110 | 80 | 105 | 106 |
| | wafer | Evaluation of | A | A | A | AA | AA | AA | A | B | B | AA | B | AA | AA |
| | | contact angle | | | | | | | | | | | | | |
| | | AlOx thickness (nm) | 2.2 | 2.1 | 2.2 | 0.8 | 0.7 | 0.6 | 2.3 | 3.6 | 2.6 | 0.7 | 2.3 | 0.9 | 0.9 |

| | | | | | | | | | | | Comparative | | | |
|---|---|---|---|---|---|---|---|---|---|---|---|---|---|---|
| | | | Examples | | | | | | | | Examples | | | |
| | | | 14 | 15 | 16 | 17 | 18 | 19 | 20 | 21 | 1 | 2 | 3 | 4 |
| Chemical | Specific | A-1 | 0.5 | 0.5 | | | | | | | | | | |
| liquid | compound | A-2 | 0.5 | | 0.5 | | | 0.45 | 0.45 | 0.45 | | | | 0.5 |
| | (parts | A-3 | | | | | | | | | | | | |
| | by mass) | A-4 | | | | | | | | | | | 1.0 | |
| | | A-5 | | | | | | | | | | | | |
| | | B-1 | | 0.5 | 0.5 | | | 0.45 | 0.45 | 0.45 | | | | |
| | | B-2 | | | | | | | | | | | | |
| | Other | C-1 | | | | | | | | | | | | |
| | compounds | C-2 | | | | | | | | | | | | |
| | (parts | D-1 | | | | | | | | | | | | |
| | by mass) | D-2 | | | | | | | | | | | | |
| | | E-1 | | | | | | | | | | | | |
| | | E-2 | | | | | | | | | | | | |
| | | F-1 | | | | 0.5 | | | | | | | | |
| | | F-2 | | | | 0.5 | 0.5 | | | | | | | |
| | | F-3 | | | | | 0.5 | | | | | | | |
| | | G-1 | | | | | | | | | | 0.5 | | |
| | | G-2 | | | | | | | | | | 0.5 | | 0.5 |
| | | H-1 | | | | | | 0.1 | | | | | | |
| | | H-2 | | | | | | | 0.1 | | | | | |
| | | H-3 | | | | | | | | 0.1 | | | | |
| | Solvent | S-1 | | | | 99.0 | 99.0 | 99.0 | 99.0 | 99.0 | 100.0 | 99.0 | 99.0 | 99.0 |
| | (parts | S-2 | 99.0 | 99.0 | 99.0 | | | | | | | | | |
| | by mass) | | | | | | | | | | | | | |
| Evaluation | W layer | Contact angle (°) | 100 | 110 | 110 | 65 | 80 | 105 | 106 | 107 | 20 | 23 | 59 | 20 |
| | wafer | Evaluation of | A | AA | AA | B | B | AA | AA | AA | C | C | C | C |
| | | contact angle | | | | | | | | | | | | |
| | | AlOx thickness (nm) | 2.3 | 0.7 | 0.7 | 3.0 | 3.2 | 0.9 | 0.9 | 0.8 | 5.0 | 5.0 | 4.2 | 5.0 |
| | Ru layer | Contact angle (°) | 90 | 110 | 111 | 68 | 65 | 106 | 106 | 108 | 55 | 51 | 57 | 55 |
| | wafer | Evaluation of | A | AA | AA | B | B | AA | AA | AA | C | C | C | C |
| | | contact angle | | | | | | | | | | | | |
| | | AlOx thickness (nm) | 2.2 | 0.7 | 0.6 | 3.7 | 3.8 | 0.9 | 0.9 | 0.8 | 5.0 | 5.0 | 5.0 | 5.0 |

From the results in Table 1, it was confirmed that the chemical liquid according to the embodiment of the present invention (Examples 1 to 16) was capable of forming a film exhibiting a high contact angle of water on a metal region in a case where the chemical liquid was brought into contact with a substrate having a metal region. On the other hand, Comparative Examples 1 and 2 not containing the specific compound did not exhibit the above-mentioned effects. In addition, Comparative Examples 3 and 4 containing only one specific compound also did not exhibit the above-mentioned effects.

From the comparison of Examples 1 to 7 and 12 with Examples 8 and 11, it was confirmed that the contact angle was larger in a case where the polar group of the specific compound was one or more groups selected from the group consisting of a nitrogen-containing group, a phosphonate group, a carboxy group, and a thiol group.

From the comparison of Examples 1 to 4 with Example 9, it was confirmed that the contact angle was larger in a case where the number of carbon atoms in the alkyl group, which is a vertical alignment group of the specific compound, was 10 or more.

From the comparison of Examples 5 to 7 and 10 with other Examples, it was confirmed that the contact angle was larger in a case of containing a first specific compound having a nitrogen-containing group as a polar group and a second specific compound having a phosphonate group or a salt thereof, a carboxy group or a salt thereof, or a thiol group as a polar group.

From the comparison of Examples 1 to 4, 7, and 12 with Example 8, it was confirmed that the contact angle was larger in a case of containing two or more third specific compounds having a polar group selected from the group consisting of a nitrogen-containing group, a phosphonate group or a salt thereof, a carboxy group or a salt thereof, and a thiol group, with the polar groups in the two or more third specific compounds being the same.

From the comparison of Example 17 with Example 18, it was confirmed that the contact angle was larger in a case where one or more of the specific compounds had a molecular weight of 600 or less.

What is claimed is:

1. A chemical liquid for manufacturing a semiconductor, comprising:
a solvent; and
two or more specific compounds,
wherein the specific compound is a compound having a polar group and a vertical alignment group.

2. The chemical liquid according to claim 1,
wherein the polar group is one or more groups selected from the group consisting of a nitrogen-containing group, a phosphate group or a salt thereof, a phosphonate group or a salt thereof, a sulfo group or a salt thereof, a carboxy group or a salt thereof, a thiol group, and a hydroxy group.

3. The chemical liquid according to claim 1,
wherein the chemical liquid contains a first specific compound having a nitrogen-containing group that is the polar group and the vertical alignment group, and a second specific compound having the polar group other than the nitrogen-containing group and the vertical alignment group.

4. The chemical liquid according to claim 3,
wherein the polar group of the second specific compound is a phosphonate group or a salt thereof, a carboxy group or a salt thereof, or a thiol group.

5. The chemical liquid according to claim 1,
wherein the chemical liquid contains two or more third specific compounds having the polar group selected from the group consisting of a nitrogen-containing group, a phosphonate group or a salt thereof, a carboxy group or a salt thereof, and a thiol group and the vertical alignment group, and the polar groups in the two or more third specific compounds are the same.

6. A chemical liquid for manufacturing a semiconductor, comprising:
a solvent; and
two or more specific compounds,
wherein the specific compound has a polar group, and a specific group selected from the group consisting of a hydrocarbon group which may have a halogen atom and a polyoxyalkylene group.

7. The chemical liquid according to claim 6,
wherein the polar group is one or more groups selected from the group consisting of a nitrogen-containing group, a phosphate group or a salt thereof, a phosphonate group or a salt thereof, a sulfo group or a salt thereof, a carboxy group or a salt thereof, a thiol group, and a hydroxy group.

8. The chemical liquid according to claim 6,
wherein the chemical liquid contains a fourth specific compound having a nitrogen-containing group that is the polar group and the specific group, and a fifth specific compound having the polar group other than the nitrogen-containing group and the specific group.

9. The chemical liquid according to claim 8,
wherein the polar group of the fifth specific compound is a phosphonate group or a salt thereof, a carboxy group or a salt thereof, or a thiol group.

10. The chemical liquid according to claim 6,
wherein the chemical liquid contains two or more sixth specific compounds having the polar group selected from the group consisting of a nitrogen-containing group, a phosphonate group or a salt thereof, a carboxy group or a salt thereof, and a thiol group and the specific group, and the polar groups in the two or more sixth specific compounds are the same.

11. The chemical liquid according to claim 1,
wherein the one or more specific compounds have a molecular weight of 600 or less.

12. The chemical liquid according to claim 1,
wherein the chemical liquid is used for treating a substrate having a metal region.

13. The chemical liquid according to claim 12,
wherein the metal region contains tungsten or ruthenium.

14. The chemical liquid according to claim 1,
wherein the chemical liquid is used for forming a film containing the two or more specific compounds only on a metal region.

15. The chemical liquid according to claim 1,
wherein the chemical liquid is used for forming a film containing the two or more specific compounds that functions as a mask in a case where a film is formed on a substrate by chemical vapor deposition.

16. A manufacturing method of a modified substrate, comprising:
a step of bringing the chemical liquid according to claim 1 into contact with a substrate having a metal region to form a film containing the two or more specific compounds on the metal region to obtain a modified substrate.

17. The manufacturing method of a modified substrate according to claim 16,
wherein the step is a step of bringing the chemical liquid into contact with the substrate, heating the substrate with which the chemical liquid has been brought into contact, and subjecting the heated substrate to a rinsing treatment to obtain a modified substrate including a film containing the two or more specific compounds formed on the metal region.

18. A manufacturing method of a laminate, further comprising:
a step of subjecting a modified substrate manufactured by the manufacturing method according to claim 16 to atomic layer deposition to form a metal film or a metal oxide film on a region other than the metal region.

19. The manufacturing method of a laminate according to claim 18, further comprising:
a step of removing a film containing the two or more specific compounds formed on the metal region.

20. The chemical liquid according to claim 6,
wherein the one or more specific compounds have a molecular weight of 600 or less.
